(19) United States
(12) Patent Application Publication
(10) Pub. No.: US 2019/0041708 A1
(43) Pub. Date: Feb. 7, 2019

(54) ARRAY SUBSTRATE AND DISPLAY DEVICE

(71) Applicant: Shenzhen China Star Optoelectronics Semiconductor Display Technology Co., Ltd., Shenzhen City GD (CN)

(72) Inventor: Qiming Gan, Shenzhen City (CN)

(21) Appl. No.: 15/579,927

(22) PCT Filed: Nov. 16, 2017
(86) PCT No.: PCT/CN2017/111339

§ 371 Date: Dec. 5, 2017

(30) Foreign Application Priority Data
Aug. 4, 2017 (CN) 201710662487.3

(51) Int. Cl. G02F 1/1362; H01L 27/02; H01L 27/12; G02F 1/1335; H01L 29/786; G02F 1/1368

(52) U.S. Cl. CPC G02F 1/136204; H01L 27/0296; H01L 27/1248; G02F 1/133514; G02F 2001/133388; H01L 29/7869; H01L 27/0266; G02F 1/1368; G02F 2001/136222; H01L 27/1225

(57) ABSTRACT

The present invention provides an array substrate and a display device. The array substrate of the present invention includes an ESD area that is provided with a color resist layer to cover and shield the ESD assembly, and thus cover and shield TFTs, to effectively isolate moisture, protect the TFTs from corrosion by the moisture and keep excellent electrical properties of the TFTs, so as to effectively reduce the potential risk of shorting caused by static electricity. The display device of the present invention involves the above array substrate to effectively isolate moisture, protect TFTs from corrosion by the moisture and keep excellent electrical properties of the TFTs, so as to effectively reduce the potential risk of shorting caused by static electricity.

### BACKGROUND OF THE INVENTION

### 1. Field of the Invention

The present invention relates to the field of display technology, and more particular to an array substrate and a display device.

### 2. The Related Arts

Liquid crystal display (LCD) has various advantages, such as thin device body, low power consumption, and being free of radiation, and has wide applications, such as liquid crystal televisions, mobile phones, personal digital assistants (PDAs), digital cameras, computer screens, and notebook computer screens, so as to take a leading position in the field of flat panel displays.

Most of the LCDs that are currently available in the market are backlighting LCDs, which comprise a liquid crystal display panel and a backlight module. The working principle of the liquid crystal display panel is that liquid crystal molecules are filled between a thin-film transistor (TFT) array substrate and a color filter (CF) substrate and a drive voltage is applied to the two substrates to control a rotation direction of the liquid crystal molecules in order to refract out light emitting from the backlight module to generate an image.

To prevent static electricity from affecting product quality, in the state of the art, it is common to provide an electro-static discharge (ESD) area around an outer circumference of an active area (AA) of the array substrate and an ESD assembly made up of diodes connected in an inverted manner is provided in such area to achieve a bettered effect of protection. In addition, the outer circumference of the AA of the array substrate is also provided with an outer lead bonding (OLB) area and a fan-out area. A printed circuit board (PCB) is connected by means of chip on film (COF) to the OLB area of a panel so as to allow an integrated circuit (IC) that is integrated on the COF to supply a signal through the OLB area to the panel.

Color-filter on array (COA) technology is a technique of integration in which a color resist layer is directly formed on the array substrate and can effectively overcome issues of light leakage resulting from positional deviation occurring in a boxing operation of an LCD and also significantly increase an aperture ratio of displaying.

In a conventional COA display panel, the array substrate generally comprises a backing plate, a TFT layer formed on the backing plate, a first passivation layer formed on the TFT layer, and a color resist layer formed on the first passivation layer. The color resist layer, however, does not cover the ESD area. In other words, the array substrate does not include a color resist layer provided in the ESD area. Referring to FIG. 1, FIG. 1 is a schematic view illustrating a cross-sectional structure of an ESD area of a conventional array substrate. The array substrate comprises, in sequence from bottom to top in the ESD area, a backing plate 11, a TFT layer 12, and a first passivation layer 13. Since no color resist layer is provided on the first passivation layer 13, the first passivation layer 13 of its own shows only poor capability of isolating moisture so that the TFT elements contained in the TFT layer 12 may be corroded by the moisture to get failure and electrical repeatability of the TFT elements becomes poor and may get shorted due to static electricity.

### SUMMARY OF THE INVENTION

Objectives of the present invention are to provide an array substrate, which has an electro-static discharge (ESD) area that is covered and shielded by a color resist layer of a thin-film transistor (TFT) so as to effectively isolate moisture and protect the TFT from corrosion by moisture to keep excellent electrical property of the TFT and thus effectively reducing potential risk of shorting caused by static electricity.

Objectives of the present invention are also to provide a display device, which involves the above-described array substrate so as to effectively isolate moisture, protect a TFT in an ESD area from corrosion by moisture to thereby keep excellent electrical property of the TFT and thus effectively reducing potential risk of shorting caused by static electricity.

To achieve the above objectives, the present invention provides an array substrate, which comprises a display area located in a central portion and an ESD area located outside the display area;

wherein the array substrate comprises, in both the display area and the ESD area, a backing plate, a TFT layer arranged on the backing plate, and a first passivation layer arranged on the TFT layer; and

the array substrate further comprises, in the ESD area, a color resist layer arranged on the first passivation layer; and

wherein the TFT layer comprises, in the ESD area, at least one ESD assembly, wherein the ESD assembly comprises a plurality of TFTs and the color resist layer covers the ESD assembly.

The array substrate is a color-filter-on-array (COA) array substrate, wherein the array substrate also comprises a color resist layer in the display area;

wherein the color resist layer in the display area comprises a plurality of red resist units, green resist units, and blue resist units arranged in an array.

The color resist layer in the ESD area is formed at the same time with one of the red resist units, the green resist units, and the blue resist units in the display area that is made first.

The color resist layer in the ESD area comprises red resist and is formed at the same time with the red resist units of the color resist layer in the display area.

The TFTs each comprise a gate electrode, a gate insulation layer, an active layer, a source electrode, and a drain electrode.

The TFTs are each an IGZO-TFT, of which the active layer is formed of a material comprising indium gallium zinc oxide (IGZO).

In the TFTs, the gate electrode is arranged on the backing plate; the gate insulation layer is arranged on the gate electrode and the backing plate; the active layer is arranged on the gate insulation layer and is corresponding to and located above the gate electrode; and the source electrode and the drain electrode are arranged on the active layer and the gate insulation layer and are respectively located on two opposite sides of the active layer.

The ESD assembly comprises two TFTs and the two TFTs are opposite to each other and are arranged in parallel.

The at least one ESD assembly is provided with a number of at least two and the at least two ESD assemblies are connected in series to each other.

The present invention also provides a display device, which comprises the array substrate described above.

The present invention further provides an array substrate, which comprises a display area located in a central portion and an ESD area located outside the display area;

wherein the array substrate comprises, in both the display area and the ESD area, a backing plate, a TFT layer arranged on the backing plate, and a first passivation layer arranged on the TFT layer; and

the array substrate further comprises, in the ESD area, a color resist layer arranged on the first passivation layer; and

wherein the TFT layer comprises, in the ESD area, at least one ESD assembly, wherein the ESD assembly comprises a plurality of TFTs and the color resist layer covers the ESD assembly;

wherein the array substrate is a COA array substrate, wherein the array substrate also comprises a color resist layer in the display area;

wherein the color resist layer in the display area comprises a plurality of red resist units, green resist units, and blue resist units arranged in an array;

wherein the color resist layer in the ESD area is formed at the same time with one of the red resist units, the green resist units, and the blue resist units in the display area that is made first;

wherein the ESD assembly comprises two TFTs and the two TFTs are opposite to each other and are arranged in parallel; and

wherein the at least one ESD assembly is provided with a number of at least two and the at least two ESD assemblies are connected in series to each other.

The efficacy of the present invention is that the present invention provides an array substrate that comprises an ESD area that is provided with a color resist layer to cover and shield the ESD assembly, and thus cover and shield TFTs, to effectively isolate moisture, protect the TFTs from corrosion by the moisture and keep excellent electrical properties of the TFTs, so as to effectively reduce the potential risk of shorting caused by static electricity. The present invention provides a display device, which involves the above array substrate to effectively isolate moisture, protect TFTs from corrosion by the moisture and keep excellent electrical properties of the TFTs, so as to effectively reduce the potential risk of shorting caused by static electricity.

### BRIEF DESCRIPTION OF THE DRAWINGS

For better understanding of the features and technical contents of the present invention, reference will be made to the following detailed description of the present invention and the attached drawings. However, the drawings are provided only for reference and illustration and are not intended to limit the present invention.

In the drawings:

FIG. 1 is a schematic view illustrating a cross-sectional structure of an

ESD area of a conventional array substrate;

FIG. 2 is a schematic view illustrating a plane of an ESD area of an array substrate according to the present invention; and

FIG. 3 is a schematic view illustrating a cross-sectional structure of the ESD area of the array substrate according to the present invention.

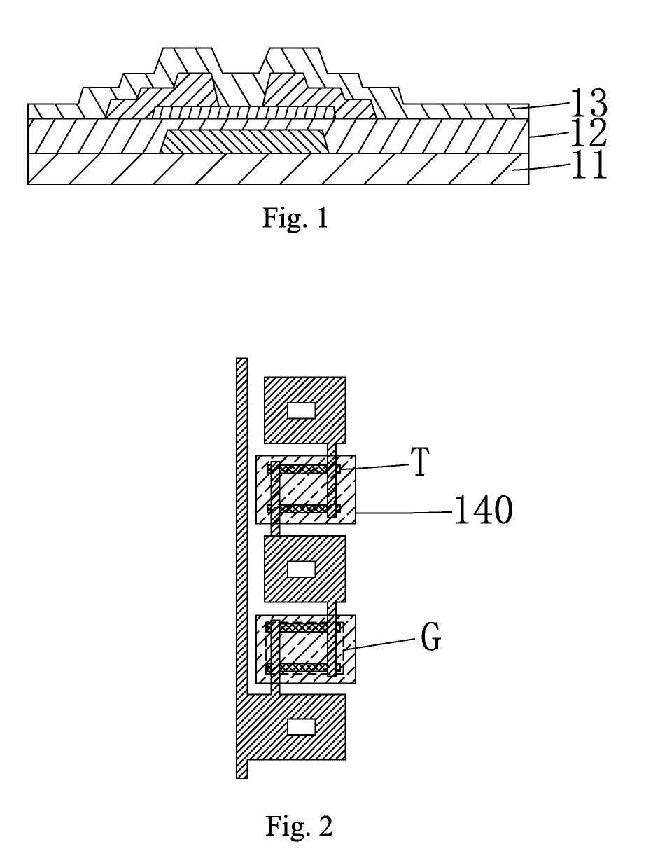

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof

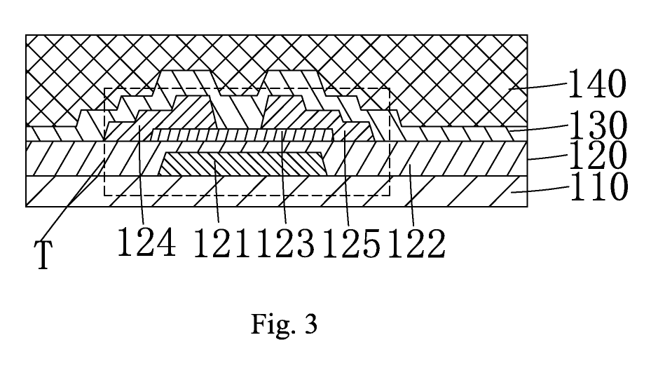

Referring to FIGS. 2-3, firstly, the present invention provides an array substrate, which comprises a display area located in a central portion and an electro-static discharge (ESD) area located outside the display area.

The array substrate can be a color-filter-on-array (COA) array substrate, which comprises, in both the display area and the ESD area, a backing plate 110, a thin-film transistor (TFT) layer 120 arranged on the backing plate 110, a first passivation layer 130 arranged on the TFT layer 120, and a color resist layer 140 arranged on the first passivation layer 130;

wherein the TFT layer 120 comprises, in the ESD area, at least one ESD assembly G, wherein the ESD assembly G comprises a plurality of TFTs T and the color resist layer 140 covers and shields the ESD assembly G.

The color resist layer 140 comprises, in the display area, a plurality of red resist units, green resist units, and blue resist units arranged in an array.

Specifically, a portion of the color resist layer 140 that is located in the ESD area is formed at the same time with one of the red resist units, the green resist units, and the blue resist units of the display area that is made first.

Further, the red resist units of the color resist layer 140 located in the display area are made first and the portion of the color resist layer 140 located in the ESD area comprises the red resist and is formed at the same time with the red resist units of the color resist layer 140 made in the display area.

Specifically, the TFTs T each comprise a gate electrode 121, a gate insulation layer 122, an active layer 123, a source electrode 124, and a drain electrode 125.

Specifically, the TFTs T are IGZO-TFT, of which the active layer 123 is made of a material comprising indium gallium zinc oxide (IGZO).

Specifically, the TFTs T are of a bottom gate structure, wherein the gate electrode 121 is arranged on the backing plate 110; the gate insulation layer 122 is arranged on the gate electrode 121 and the backing plate 110; the active layer 123 is arranged on the gate insulation layer 122 and is corresponding to and located above the gate electrode 121; and the source electrode 124 and the drain electrode 125 are both arranged on the active layer 123 and the gate insulation layer 122 and are respectively located on two opposite sides of the active layer 123.

Specifically, the ESD assembly G comprises two TFTs T, and the two

TFTs T are opposite to each other and are arranged in parallel.

Specifically, the at least one ESD assembly G is provided with a number of at least two and the at least two ESD assemblies G are connected in series.

In the array substrate of the present invention, the ESD area is provided with a color resist layer that covers and shields the ESD assembly G, namely covering and shielding the TFTs T. The larger an area around the ESD assembly G and covered by the color resist layer is, the more distant the ESD assembly G is spaced from the surrounding environment, this being equivalent to an increase in thickness of a protective cover to more effectively isolate moisture and protect the TFTs T from corrosion by the moisture and keep excellent electrical properties of the TFTs T, so as to reduce the potential risk of shorting caused by static electricity.

Based on the array substrate described above, the present invention also provides a display device, which comprises the array substrate that has been described above. Technical features of the array substrate will not be repeatedly described herein.

In summary, the present invention provides an array substrate that comprises an ESD area that is provided with a color resist layer to cover and shield the ESD assembly, and thus cover and shield TFTs, to effectively isolate moisture, protect the TFTs from corrosion by the moisture and keep excellent electrical properties of the TFTs, so as to effectively reduce the potential risk of shorting caused by static electricity. The present invention provides a display device, which involves the above array substrate to effectively isolate moisture, protect TFTs from corrosion by the moisture and keep excellent electrical properties of the TFTs, so as to effectively reduce the potential risk of shorting caused by static electricity.

Based on the description given above, those having ordinary skills in the art may easily contemplate various changes and modifications of he technical solution and the technical ideas of the present invention. All these changes and modifications are considered belonging to the protection scope of the present invention as defined in the appended claims.

What is claimed is:

1. An array substrate, comprising a display area located in a central portion and an electro-static discharge (ESD) area located outside the display area;
wherein the array substrate comprises, in both the display area and the ESD area, a backing plate, a thin-film transistor (TFT) layer arranged on the backing plate, and a first passivation layer arranged on the TFT layer; and
the array substrate further comprises, in the ESD area, a color resist layer arranged on the first passivation layer; and
wherein the TFT layer comprises, in the ESD area, at least one ESD assembly, wherein the ESD assembly comprises a plurality of TFTs and the color resist layer covers the ESD assembly.

2. The array substrate as claimed in claim 1, which is a color-filter-on-array (COA) array substrate, wherein the array substrate also comprises a color resist layer in the display area;
wherein the color resist layer in the display area comprises a plurality of red resist units, green resist units, and blue resist units arranged in an array.

3. The array substrate as claimed in claim 2, wherein the color resist layer in the ESD area is formed at the same time with one of the red resist units, the green resist units, and the blue resist units in the display area that is made first.

4. The array substrate as claimed in claim 2, wherein the color resist layer in the ESD area comprises red resist and is formed at the same time with the red resist units of the color resist layer in the display area.

5. The array substrate as claimed in claim 1, wherein the TFTs each comprise a gate electrode, a gate insulation layer, an active layer, a source electrode, and a drain electrode; and
the TFTs are each an IGZO-TFT, of which the active layer is formed of a material comprising indium gallium zinc oxide (IGZO).

6. The array substrate as claimed in claim 1, wherein the TFTs each comprise a gate electrode, a gate insulation layer, an active layer, a source electrode, and a drain electrode;
wherein the gate electrode is arranged on the backing plate; the gate insulation layer is arranged on the gate electrode and the backing plate; the active layer is arranged on the gate insulation layer and is corresponding to and located above the gate electrode; and the source electrode and the drain electrode are arranged on the active layer and the gate insulation layer and are respectively located on two opposite sides of the active layer.

7. The array substrate as claimed in claim 1, wherein the ESD assembly comprises two TFTs and the two TFTs are opposite to each other and are arranged in parallel.

8. The array substrate as claimed in claim 1, wherein the at least one ESD assembly is provided with a number of at least two and the at least two ESD assemblies are connected in series to each other.

9. A display device, comprising the array substrate as claimed in claim 1.

10. An array substrate, comprising a display area located in a central portion and an electro-static discharge (ESD) area located outside the display area;
wherein the array substrate comprises, in both the display area and the ESD area, a backing plate, a thin-film transistor (TFT) layer arranged on the backing plate, and a first passivation layer arranged on the TFT layer; and
the array substrate further comprises, in the ESD area, a color resist layer arranged on the first passivation layer; and
wherein the TFT layer comprises, in the ESD area, at least one ESD assembly, wherein the ESD assembly comprises a plurality of TFTs and the color resist layer covers the ESD assembly;
wherein the array substrate is a color-filter-on-array (COA) array substrate, wherein the array substrate also comprises a color resist layer in the display area;
wherein the color resist layer in the display area comprises a plurality of red resist units, green resist units, and blue resist units arranged in an array;
wherein the color resist layer in the ESD area is formed at the same time with one of the red resist units, the green resist units, and the blue resist units in the display area that is made first;
wherein the ESD assembly comprises two TFTs and the two TFTs are opposite to each other and are arranged in parallel; and
wherein the at least one ESD assembly is provided with a number of at least two and the at least two ESD assemblies are connected in series to each other.

11. The array substrate as claimed in claim 10, wherein the color resist layer in the ESD area comprises red resist and is formed at the same time with the red resist units of the color resist layer in the display area.

12. The array substrate as claimed in claim 10, wherein the TFTs each comprise a gate electrode, a gate insulation layer, an active layer, a source electrode, and a drain electrode; and
the TFTs are each an IGZO-TFT, of which the active layer is formed of a material comprising indium gallium zinc oxide (IGZO).

13. The array substrate as claimed in claim 10, wherein the TFTs each comprise a gate electrode, a gate insulation layer, an active layer, a source electrode, and a drain electrode;
wherein the gate electrode is arranged on the backing plate; the gate insulation layer is arranged on the gate electrode and the backing plate; the active layer is arranged on the gate insulation layer and is corresponding to and located above the gate electrode; and the source electrode and the drain electrode are arranged on the active layer and the gate insulation layer and are respectively located on two opposite sides of the active layer.
